(19) United States
(12) Patent Application Publication
(10) Pub. No.: US 2026/0366134 A1
(43) Pub. Date: Nov. 19, 2026

(54) HIGH THERMAL CONDUCTIVITY AMORPHOUS NITRIDE COATING AND PREPARATION METHOD AND APPLICATIONS THEREOF

(71) Applicant: Shanghai University, Shanghai (CN)

(72) Inventor: Zhaohe Gao, Shanghai (CN)

(73) Assignee: Shanghai University, Shanghai (CN)

(21) Appl. No.: 19/572,750

(22) Filed: Mar. 19, 2026

(30) Foreign Application Priority Data
Mar. 24, 2025 (CN) 202510351351.5

(51) Int. Cl. C23C 14/06; C23C 14/02; C23C 14/35; C23C 14/54; H10D 64/27

(52) U.S. Cl. CPC C23C 14/0652; C23C 14/02; C23C 14/0647; C23C 14/352; C23C 14/54; H10D 64/514

(57) ABSTRACT

The present invention relates to a high thermal conductivity amorphous nitride coating, as well as a preparation method and applications thereof. The high thermal conductivity amorphous nitride coating comprises crystalline phases and an amorphous matrix, wherein the crystalline phases are dispersed within the amorphous matrix. The amorphous matrix is SiNx amorphous phase, and the crystalline phases include TiN, or BN, or AlN. Compared with the prior techniques, the present invention employs a precise microstructure control strategy to fabricate a dual-phase nitride coating, which overcomes the intrinsic limitation that amorphous materials generally exhibit low thermal conductivity of about 2 W/m·K. The invention enables nitride coatings with dual-phase structures such as SiNx/TiN, SiNx/BN, or SiNx/AlN to achieve thermal conductivity as high as 100 W/m·K. The coating can be widely applied in electronic chips, LEDs, optical devices, lasers, and other related fields.

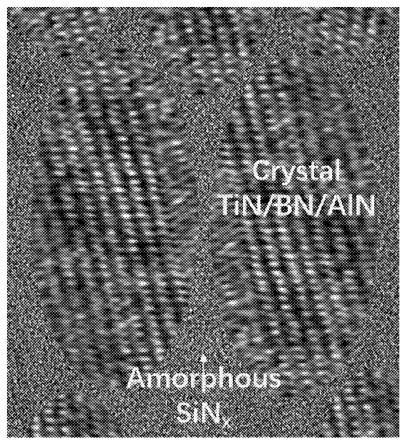

### CROSS-REFERENCE TO RELATED APPLICATION

This application claims the priority benefit of China application serial no. 202510351351.5, filed on Mar. 24, 2025. The entirety of the above-mentioned patent application is hereby incorporated by reference herein and made a part of this specification.

### BACKGROUND

### Technical Field

The present invention relates to the field of coating preparation technologies, and particularly relates to a high thermal conductivity amorphous nitride coating, as well as a preparation method and applications thereof.

### Description of Related Art

Silicon nitride (Si₃N₄) coatings have been widely used in the semiconductor field due to their excellent physical, chemical, and mechanical properties.

In chip manufacturing, silicon nitride is commonly used as a passivation layer to protect semiconductor surfaces from environmental contamination. In photolithography processes, silicon nitride is used as an anti-reflection coating (ARC) to reduce optical interference and improve pattern clarity and resolution. In crystalline silicon solar cells, silicon nitride functions as both a surface passivation layer and an anti-reflection coating to enhance light absorption and improve cell efficiency. In metal-oxide-semiconductor (MOS) devices, silicon nitride may serve as a gate oxide layer or dielectric layer, providing excellent electrical insulation.

In MOS devices, heat dissipation of the gate dielectric is an important issue, particularly in applications involving high performance and high power density. Because gate dielectrics in MOS devices are typically insulating materials (such as amorphous silicon dioxide, amorphous silicon nitride, and hafnium dioxide), their thermal conductivity is extremely low, typically in the range of 2-5 W/m·K. Therefore, effective heat dissipation is critical for maintaining device performance and reliability.

Accordingly, there is an urgent need for a novel gate dielectric coating material that maintains excellent insulating properties while exhibiting relatively high thermal conductivity, thereby enabling semiconductor devices to dissipate heat more efficiently and preventing excessive operating temperatures that could degrade device performance or even cause device failure.

Chinese patent CN201710312291.1 discloses a nanocomposite material, a nanocomposite coating for strengthening aluminum alloy die-casting molds, and applications thereof. The nanocomposite material comprises titanium nitride nanocrystals and an encapsulating layer surrounding the titanium nitride nanocrystals. The encapsulating layer includes amorphous silicon nitride and amorphous nickel, wherein the amorphous nickel is present as a metallic free phase and is uniformly dispersed in the amorphous silicon nitride. However, the coating disclosed in that patent contains conductive nickel, which prevents it from being used as a dielectric layer in semiconductor devices. In addition, the coating is mainly intended for surface strengthening of aluminum alloys.

### SUMMARY

The objective of the present invention is to provide a high thermal conductivity amorphous nitride coating, as well as a preparation method and applications thereof.

The amorphous nitride coating of the present invention can achieve a thermal conductivity as high as 100 W/m·K. The high thermal conductivity amorphous nitride coating can be applied to devices represented by metal-oxide-semiconductor (MOS) devices, thereby significantly improving heat dissipation characteristics.

The above objective of the present invention can be achieved through the following

### Technical Solutions.

A high thermal conductivity amorphous nitride coating is provided, wherein the coating comprises crystalline phases and an amorphous matrix, and the crystalline phases are dispersed in the amorphous matrix.

The amorphous matrix is amorphous SiNx, where x ranges from 1 to 1.5, and the crystalline phases include TiN, or BN, or AlN.

Preferably, the volume fraction ratio of the crystalline phases to the amorphous matrix is 1-100: 1-100, and the high thermal conductivity of the nitride coating is achieved through precise regulation of the dual-phase structure and elemental composition.

The present invention further provides a preparation method for the high thermal conductivity amorphous nitride coating, comprising the following steps:
S1. Pretreating a substrate;
S2. Preparing the high thermal conductivity amorphous nitride coating by depositing the coating on the pretreated substrate using magnetron sputtering.

Preferably, in step S1, the substrate material is selected from silicon wafers, metal substrates, or ceramic substrates.

Preferably, the pretreatment process in step S1 comprises: fixing the substrate onto a sample holder in a magnetron sputtering chamber, evacuating the chamber, introducing argon and nitrogen gases, and heating the substrate to obtain the pretreated substrate.

More preferably:
the vacuum degree is ≤8.0×10⁻⁶ mBar.

More preferably:
the flow rate of argon is 20-40 sccm, and the flow rate of nitrogen is 10-30 sccm.

More preferably:
the heating temperature is 20-500 °C.

Preferably, in step S2, the sputtering targets used for magnetron sputtering are selected from any combination of:

Si target and Ti target; Si target and B target; Si target and Al target.

More preferably:
the RF or DC sputtering power of the Si target is 50-1000 W,
the RF or DC sputtering power of the Ti target is 50-1000 W,
the RF or DC sputtering power of the B target is 50-1000 W,
and the RF or DC sputtering power of the Al target is 50-1000 W.

Preferably, the thickness of the deposited high thermal conductivity amorphous nitride coating is 1-5000 nm.

The present invention also provides applications of the high thermal conductivity amorphous nitride coating in electronic chips, LEDs, optical devices, and laser devices.

Preferably, the high thermal conductivity amorphous nitride coating is used for preparing a mask layer on semiconductor silicon wafers.

### Advantages of the Invention

Compared with the prior art, the present invention has the following advantages:

A dual-phase nitride coating with a thickness of 1-5000 nm, including SiNx/TiN, SiNx/BN, or SiNx/AlN, can be deposited on semiconductor silicon wafers or other substrates using magnetron sputtering.

By employing a precise microstructure control technique, the invention forms a dual-phase nitride coating that overcomes the limitation of conventional amorphous materials having low thermal conductivity (~2 W/m·K). The dual-phase nitride coatings such as SiNx/TiN, SiNx/BN, or SiNx/AlN can achieve thermal conductivity up to 100 W/m·K and can be widely applied in electronic chips, LEDs, optical devices, and laser devices.

The preparation method of the high thermal conductivity amorphous nitride coating is simple and suitable for large-scale industrial production.

### BRIEF DESCRIPTION OF THE DRAWINGS

FIGURE is a schematic structural diagram of the high thermal conductivity amorphous nitride coating according to the present invention.

### DESCRIPTION OF THE EMBODIMENTS

The following sections provide a detailed description of the present invention with reference to the accompanying drawings and specific embodiments. These embodiments are based on the technical solutions of the present invention and offer detailed implementation methods and specific operational procedures. However, the scope of protection of the present invention is not limited to the embodiments described below.

### Embodiment 1

A method for preparing a high thermal conductivity amorphous nitride coating is provided, comprising the following steps.

S1. Pretreating the substrate

A silicon wafer is placed and fixed on a sample holder in a magnetron sputtering chamber. The chamber is evacuated to 8.0×10⁻mBar, argon is introduced at 20 sccm, nitrogen is introduced at 10 sccm, and the substrate temperature is set to 300 °C, thereby obtaining a pretreated substrate.

S2. Depositing SiNx/TiN coating

Magnetron sputtering is used to deposit a SiNx/TiN coating on the pretreated silicon wafer.

The RF sputtering powers of the Si target and Ti target are set to 80 W and 400 W, respectively. The silicon wafer rotates at 5 r/min to achieve co-deposition of Si and Ti. After 1 hour, the power supply is turned off to obtain the SiNx/TiN coating.

The thermal conductivity of the SiNx/TiN coating is measured using Time-domain Thermoreflectance (TDTR), and the thermal conductivity is 23.5 W/m·K.

### Embodiment 2

A method for preparing a high thermal conductivity amorphous nitride coating is provided, comprising the following steps.

S1. Pretreating the substrate

A silicon wafer is placed and fixed on a sample holder in a magnetron sputtering chamber. The chamber is evacuated to 8.0×10⁻⁶ mBar, argon is introduced at 35 sccm, nitrogen is introduced at 25 sccm, and the substrate temperature is set to 500 °C, thereby obtaining a pretreated substrate.

S2. Depositing SiNx/BN coating

Magnetron sputtering is used to deposit a SiNx/BN coating on the pretreated silicon wafer.

The sputtering powers of the Si target and B target are set to 120 W and 600 W, respectively. The silicon wafer rotates at 5 r/min to achieve co-deposition of Si and B. After 2 hours, the power supply is turned off to obtain the SiNx/BN coating.

The thermal conductivity of the SiNx/BN coating is measured using Time-domain Thermoreflectance (TDTR), and the thermal conductivity is 103.2 W/m·K.

### Embodiment 3

A method for preparing a high thermal conductivity amorphous nitride coating is provided, comprising the following steps.

S1. Pretreating the substrate

A silicon wafer is placed and fixed on a sample holder in a magnetron sputtering chamber. The chamber is evacuated to 8.0×10⁻⁶ mBar, argon is introduced at 40 sccm, nitrogen is introduced at 18 sccm, and the substrate temperature is set to 50 °C, thereby obtaining a pretreated substrate.

S2. Depositing SiNx/AlN coating

Magnetron sputtering is used to deposit a SiNx/AlN coating on the pretreated silicon wafer.

The sputtering powers of the Si target and Al target are set to 150 W and 400 W, respectively. The silicon wafer rotates at 5 r/min to achieve co-deposition of Si and Al. After 1 hour, the power supply is turned off to obtain the SiNx/AlN coating.

The thermal conductivity of the SiNx/AlN coating is measured using Time-domain Thermoreflectance (TDTR), and the thermal conductivity is 68.3 W/m·K.

The foregoing description of the embodiments is intended to enable those skilled in the art to understand and practice the invention. Those skilled in the technique will readily recognize that various modifications to these embodiments can be made, and the general principles described herein can be applied to other embodiments without requiring creative effort. Therefore, the present invention is not limited to the above embodiments. Improvements and modifications made by those skilled in the art based on the disclosure of the present invention, without departing from the scope of the invention, should be within the scope of protection of the present invention.

What is claimed is:

1. A high thermal conductivity amorphous nitride coating, characterized in that the coating comprises crystalline phases and an amorphous matrix, wherein the crystalline phases are dispersed within the amorphous matrix,
the amorphous matrix is amorphous SiNx, wherein x ranges from 1 to 1.5,
and the crystalline phases comprise TiN, or BN, or AlN.

2. The high thermal conductivity amorphous nitride coating according to claim 1, wherein a volume fraction ratio of the crystalline phases to the amorphous matrix ranges from 1-100: 1-100.

3. A method for preparing the high thermal conductivity amorphous nitride coating according to claim 1, comprising the following steps:
S1. pretreating a substrate;
S2. preparing the high thermal conductivity amorphous nitride coating by depositing the coating on the surface of the substrate pretreated in step S1 using magnetron sputtering.

4. The method according to claim 3, wherein the substrate material is selected from a silicon wafer, a metal substrate, or a ceramic substrate.

5. The method according to claim 3, wherein the substrate pretreatment in step S1 comprises:
fixing the substrate on a sample holder in a magnetron sputtering chamber, evacuating the chamber, introducing argon and nitrogen gases, and heating the substrate to obtain the pretreated substrate.

6. The method according to claim 5, wherein:
the vacuum degree is less than or equal to 8.0 ×10-6 mBar;
the flow rate of argon is 20-40 sccm; the flow rate of nitrogen is 10-30 sccm;
and the heating temperature is 20-500 °C.

7. The method according to claim 3 wherein in step S2 the magnetron sputtering deposition uses target materials selected from any one of the following combinations:
Si target and Ti target, Si target and B target, or Si target and Al target.

8. The method according to claim 7, wherein:
the RF or DC sputtering power of the Si target is 50-1000 W;
the RF or DC sputtering power of the Ti target is 50-1000 W;
the RF or DC sputtering power of the B target is 50-1000 W;
and the RF or DC sputtering power of the Al target is 50-1000 W.

9. The method f according to claim 3, characterized in that in step S2, the thickness of the high thermal conductivity amorphous nitride coating deposited on the pretreated substrate surface is 1 to 5000 nm.

10. Use of the high thermal conductivity amorphous nitride coating according to claim 1 in electronic chips, LEDs, optical devices, and laser devices.

11. A method for preparing the high thermal conductivity amorphous nitride coating according to claim 2, comprising the following steps:
S1. pretreating a substrate;
S2. preparing the high thermal conductivity amorphous nitride coating by depositing the coating on the surface of the substrate pretreated in step S1 using magnetron sputtering.

12. Use of the high thermal conductivity amorphous nitride coating according to claim 1 in electronic chips, LEDs, optical devices, and laser devices.
